(19) United States
(12) Patent Application Publication
(10) Pub. No.: US 2003/0106489 A1
(43) Pub. Date: Jun. 12, 2003

(54) Method for epitaxially growing a lead zirconate titanate thin film

(75) Inventors: Hsiang-Lan Lung, Hsinchu (TW); Hsu-Shun Chen, Muli (TW); Sheng-Chih Lai, Taichung (TW)

Correspondence Address: J C PATENTS, INC., 4 VENTURE, SUITE 250, IRVINE, CA, 92618, US

(73) Assignee: MACRONIX INTERNATIONAL CO., LTD., HSINCHU (TW)

(21) Appl. No.: 10/065,208

(22) Filed: Sep. 25, 2002

(30) Foreign Application Priority Data
Sep. 28, 2001 (TW) 90124031

(51) Int. Cl. C30B 23/00; C30B 25/00; C30B 28/12; C30B 28/14

(52) U.S. Cl. 117/84

(57) ABSTRACT

An epitaxial growing method for a lead zirconate titanate (PZT) thin film is described. A layer of lanthanum nickel oxide (LNO) thin film is grown on a substrate by an in-situ method, wherein the lattice structure of the lanthanum nickel oxide thin film is similar to the desired lattice structure of the PZT thin film. Moreover, the lattice parameters of the lanthanum nickel oxide thin film are also similar to the desired lattice parameters of the PZT thin film. A PZT thin film with the desired lattice structure is then epitaxially grown at low temperature on the LNO thin film at 350 degrees Celsius to 500 degrees Celsius.

### CROSS REFERENCE TO RELATED APPLICATIONS

This application claims the priority benefit of Taiwan application serial no. 90124031, filed Sept. 28, 2001.

### BACKGROUND OF INVENTION

1. Field of Invention

The present invention relates to a fabrication method for a high dielectric constant (k) thin film. More particularly, the present invention relates to a method for epitaxially growing a lead zirconate titanate (PbZrₓTi₁₋ₓO₃, PZT) thin film.

2. Description of Related Art

Lead zirconate titanate (PZT) is a multi-functional material. The application of lead zirconate titanate, as described hereinbelow, includes as a high-k material, a ferroelectric material, a piezoelectric material and a pyroelectric material.

Lead zirconate titanate thin film has a high dielectric constant, therefore it is applicable for the fabrication of a dynamic random access memory. The expression “high dielectric constant” refers to a dielectric constant greater than 50 at device operating temperature. Since the integration in a dynamic random access memory constantly increases, the dimension of a memory cell correspondingly diminishes. The area of the capacitor for storing information thereby decreases. In order to maintain a capacitance for the appropriate signal to noise ratio (S/N ratio) during a reading/writing operation, a high dielectric constant material such as lead zirconate titanate is used as the dielectric layer for the capacitor.

Additionally, the lead zirconate titanate thin film has the characteristic of high spontaneous polarization, which means a polarization induced by an electric field does not vanish, but remains as either a positive residual polariation or a negative residual polarization (Pᵣ⁺or Pᵣ⁻, wherein Pᵣ refers to residual polarization) even after the electric field is cleared. The PZT thin film, as a result, may serve as a type of non-volatile memory (NVM), known as ferroelectric random access memory (FeRAM). A FeRAM has a low read/write voltage, and a faster processing speed for the read or write operation (<<100 ns). Moreover, the number of steps for the manufacturing of a FeRAM is less.

Moreover, the lead zirconate titanate thin film has a high piezoelectric constant. A detectable potential difference is generated after a pressure is applied to a lead zirconate titanate thin film. A PZT thin film is applicable in various types of piezoelectric device, for example, pressure or vibration sensors, actuators or voltage generators, etc.

A lead zirconate titanate thin film also has a high pyroelectric constant. The energy generated after an absorption of infrared light when a PZT thin film is subjected under an infrared light is sufficient to provide a detectable potential difference. A PZT thin film, therefore, can use in an infrared sensor or a thermometer.

Although a lead zirconate titanate thin film is multi-functional, there are problems in applying a PZT thin film due to its high manufacturing temperature, especially applying a PZT thin film as a capacitor dielectric layer. The fabrication for a PZT thin film as disclosed in U.S. Pat. No. 5,589,284 includes forming a seed layer on the bottom electrode of a capacitor. The seed layer includes strontium ruthenate (SrRuO₃), barium ruthenate (BaRuO₃) or calcium iridate (CalrO₃), etc. A layer of the PZT thin film is then deposited on the seed layer at a temperature of about 150 degrees Celsius. An annealing is further conducted at a temperature of about 500 degrees Celsius to form the high dielectric constant Perovskite phase lattice structure, which is desired crystal phase for a PZT thin film as a capacitor dielectric.

The fabrication method, provided by U.S. Pat. No. 5,817,170, includes forming a seed layer of PbTiO₃ on a bottom electrode. A layer of PZT thin film is then deposited on the seed layer at a lower temperature followed by an annealing step conducted at a temperature of 550 degrees Celsius to 650 degrees Celsius. Similarly, the fabrication method for a (Pb,La)TiO₃ (PLT) thin film as disclosed in the U.S. Pat. No. 5,998,236 is to deposit a PZT thin film and anneal the PLT thin film at a temperature of 525 degrees Celsius to 550 degrees Celsius.

Since the conventional approach in forming a PZT thin film requires an annealing at a temperature above 500 degrees Celsius. The formation for the PZT thin film must precede the fabrication of metal interconnects. Many problems are associated with the conventional approach. For example, the machinery used in the manufacturing for the metal layer and the dielectric layer is easily contaminated by the PZT thin film. Moreover, the plasma used in the manufacturing of the metal interconnects and the hydrogen gas that is generated in the manufacturing of the metal interconnects easily induce damages on the ferroelectric capacitor.

### SUMMARY OF INVENTION

The present invention provides a fabrication method for a lead zirconate titanate (PZT) thin film, wherein the lead zirconate titanate thin film, formed under a low temperature, has the desired lattice structure and electrical property to prevent the aforementioned problems occurring in the prior art.

The lead zirconate titanate thin film formed according to the present invention includes an in-situ formation of a layer of a lanthanum nickel oxide (LaNiO₃, LNO) thin film, wherein the desired lattice structure is same as those of the PZT thin film.

Moreover, the lattice parameters of the LNO thin film are also similar to those of the PZT thin film. After this, a PZT thin film is epitaxially grown on the LNO thin film by the in-situ method. The in-situ method described herein implies a deposition of a thin film, wherein the desired lattice structure for the thin film is concurrently formed.

The in-situ method of the present invention is different from the conventional approach, in which a low temperature deposition is conducted, followed by a high temperature annealing to obtain the PZT thin film with the desired structure.

Accordingly, the PZT thin film of the present invention is formed at a temperature far lower than that in the conventional practice. Moreover, the metal interconnect may form before the fabrication of the capacitor to prevent the problems of interconnect failure due to oxidation, contamination of the reaction chamber by the PZT thin film, or damages inflicted upon the capacitor by plasma or hydrogen. The approach of fabricating a metal interconnect, followed by the fabrication of a capacitor is know as a capacitor over interconnect (COI) process. Additionally, the PZT thin film is formed at a lower temperature according to the present invention. The PZT thin film of the present invention is, therefore, applicable in the fabrication for a ferroelectric memory device, a piezoelectric device or a pyroelectric device, in which the metal interconnect is better prevented from being damaged by high temperature.

It is to be understood that both the foregoing general description and the following detailed description are exemplary, and are intended to provide further explanation of the invention as claimed.

### BRIEF DESCRIPTION OF DRAWINGS

The accompanying drawings are included to provide a further understanding of the invention, and are incorporated in and constitute as a part of this specification.

The drawings illustrate embodiments of the invention and, together with the description, serve to explain the principles of the invention. In the drawings,

FIG. 1is a schematic diagram, illustrating the fabrication method for a capacitor and a lead zirconate titanate thin film of the capacitor according to an aspect of the present invention.

FIG. 2A is a transmission electron cross-section micrograph of a COI FeRAM structure formed according to an aspect of the present invention;

FIG. 2B is an enlarged cross-sectional view of a part of the COI FeRAM plug and capacitor in FIG. 2A;

FIG. 2C is an enlarged cross-sectional view of a part of the LNO film and the PZT film in the COI FeRAM capacitor shown in FIG. 2B; e.

FIGS. 3A & 3B are transmission electron top view micrographs of a PZT thin film formed at 350 degrees Celsius and 450 degrees Celsius, respectively according to a preferred embodiment of the present invention

FIG. 4 is an X-ray diffraction pattern of a PZT thin film formed at 325 degrees Celsius to 450 degrees Celsius according to an aspect of the present invention.

FIGS. 5A, 5B and 5C are ferroelectric hysteresis loops of a PZT thin film formed at 375 degrees Celsius, 400 degrees Celsius and 450 degrees Celsius, respectively according to an aspect of the present invention.

### DETAILED DESCRIPTION

This aspect of the present invention is directed toward the fabrication method for a capacitor and a lead zirconate titanate thin film of the capacitor, wherein the capacitor and the lead zirconate titanate thin film of the capacitor are formed according to the present invention.

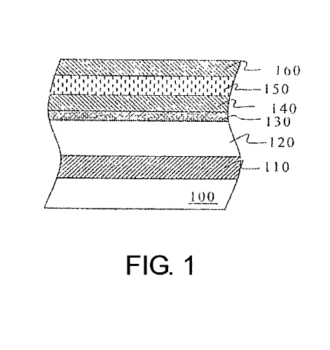

Referring to FIG. 1, a dielectric layer 100 is provided, wherein underlying the dielectric layer 100 includes a CMOS device or other metal layers, and overlying the dielectric layer 100 includes the top most layer of a metal interconnect structure 110 and a dielectric layer 120. The dielectric layer 120 includes silicon oxide formed by plasma enhance chemical vapor deposition (PECVD). The reason for forming the metal interconnect structure 110 at this stage of the manufacturing process, as disclosed above, is because the PZT thin film of the present invention may form at a lower temperature, for example, below 500 degrees Celsius.

Continuing to FIG. 1, a barrier layer 130, such as, titanium titanium nitride, titanium oxide, titanium tungsten nitride, titanium aluminum nitride, tantalum nitride platinum or a combination of the above elements is formed on top of the dielectric layer 120. After this, by an in-situ method, a lanthanum nickel oxide (LNO) layer 140 is formed on the barrier layer 130 as the bottom electrode by sputtering at about 350 degrees Celsius, wherein the mole ratio for La and Ni in the lanthanum nickel oxide layer 140 is about 1:1.3. The detail process conditions are listed in Table 1.

TABLE 1
Process Conditions for LaNiO₃ Bottom Electrode

| | |
|---|---|
| Target | La₂O₃ + NiO 1000° C. sintered |
| Substrate Temperature | 350° C. |
| Sputtering Power | 3 W/cm² |
| Sputtering Atmosphere | Ar/O₂ = 75/25 |
| Sputtering Pressure | 5 mTorr |

Still referring to FIG. 1, by the in-situ sputtering method, a PZT thin film is formed on the lanthanum nickel oxide layer 140 and concurrently epitaxially growing the PZT thin film 150 with the desired lattice structure. The system where the PZT thin film is formed contains pure argon, and oxygen is definitely avoided in the system to prevent a lowering of the of the PZT thin film. The detail process conditions are list in Table 2. An upper electrode 160 is then formed on the PZT thin film 150. The upper electrode 160 is formed with, for example, LNO, platinum (Pt), iridium dioxide (IrO₂), ruthenium dioxide (RuO₂), iridium (Ir) or ruthenium (Ru) by sputtering or chemical vapor deposition (CVD) method.

TABLE 1
Process Conditions of PZT Deposition

| | |
|---|---|
| Target | PbO + ZrO₂ + TiO₂ hot press sintered |
| Substrate | LaNiO₃ |
| Substrate Temperature | 350° C. to 450° C. |
| Sputtering Power | 3 W/cm² |
| Sputtering Atmosphere | Pure Ar |
| Sputtering Pressure | 5 mTorr |

Experimental Results

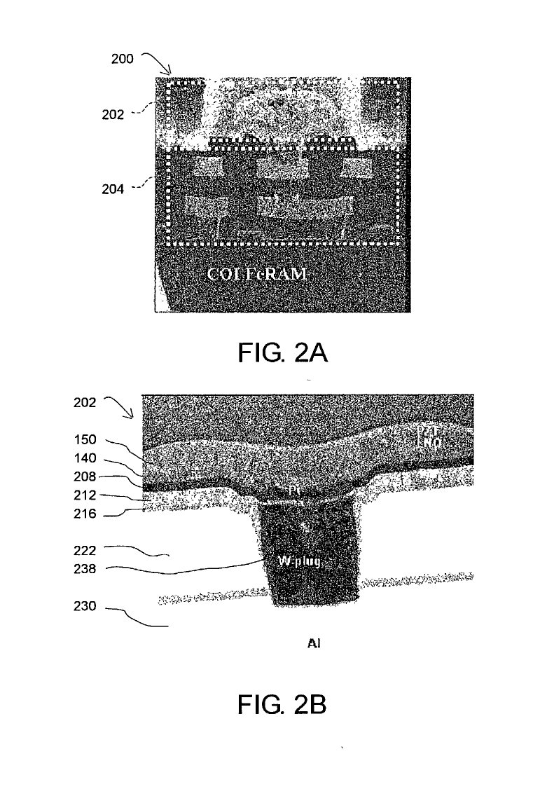

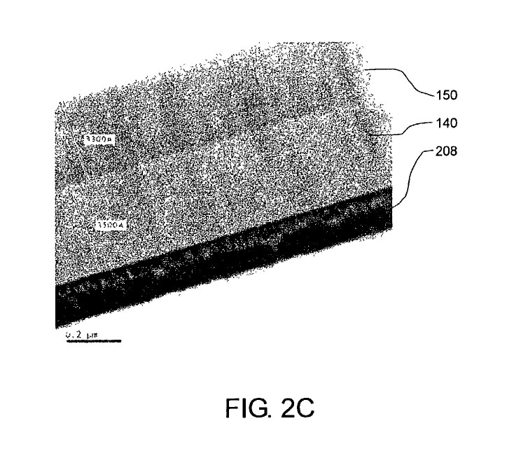

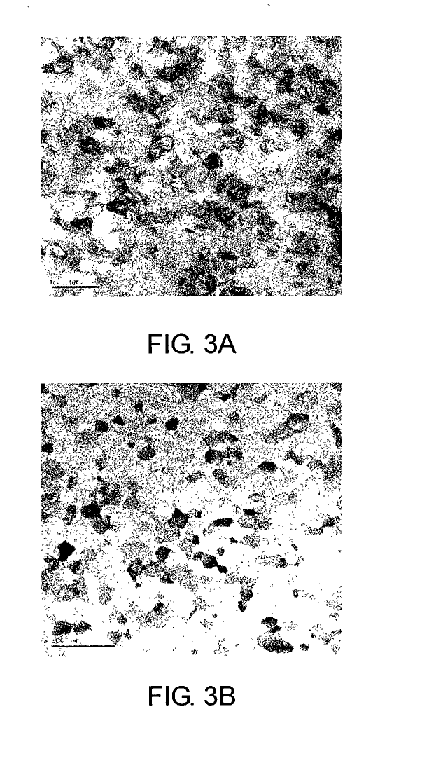

Referring to FIGS. 2A to 2C, wherein FIG. 2A is a transmission electron cross-section micrograph of a COI FeRAM structure formed according to an aspect of the present invention. FIG. 2B is an enlarged cross-sectional view of a part of the COI FeRAM plug and capacitor in FIG. 2A, FIG. 2C is an enlarged cross-section view of a part of the LNO film (140) and the PZT film (150) in the COI FeRAM capacitor shown in FIG. 2B, wherein the LNO film (140) is formed under 350 degrees Celsius and the PZT film (150) is formed under 400 degrees Celsius.

As shown FIG. 2A, the COI FeRAM 200 is sectioned into an upper FeRAM capacitor 202 and a lower CMO logic region 204. As shown in FIG. 2B, under the LNO thin film 140, a platinum layer 208, a titanium nitride layer 212 and a titanium layer are sequentially formed. Further, the titanium layer 216 is disposed above the silicon dioxide layer 222 and the silicon dioxide layer is disposed above an aluminum layer 230. A tungsten plug 238 is further formed in the silicon dioxide layer 222 to electrically connect the capacitor and the aluminum layer 230. Thereafter, as shown in FIG. 2C, the PZT thin film epitaxially grows in an upward direction along the lattice of the LNO thin film. The LNO thin film 140 and the PZT thin film 150 are formed by sputtering.

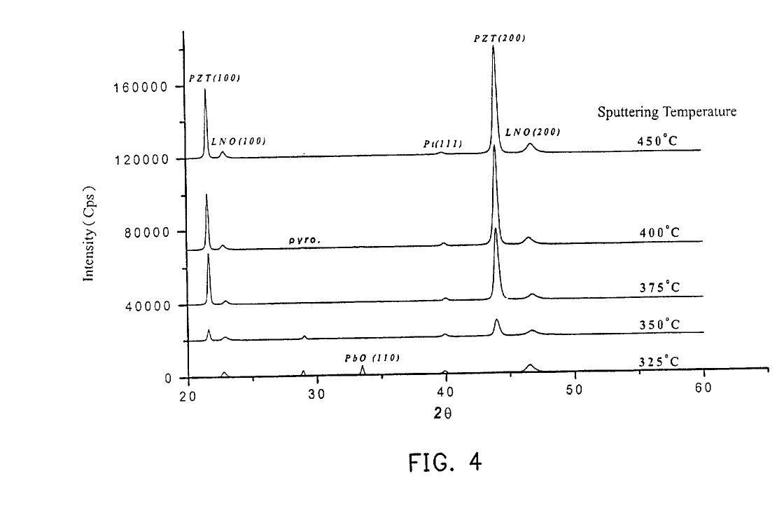

FIGS. 3A & 3B are transmission electron micrographs of the top view of a PZT thin film 150 formed at a temperature of about 350 degrees Celsius and 450 degrees Celsius, respectively. As shown in FIGS. 3A and 3B, the crystal property of the PZT thin film formed at 450 degrees Celsius is better than that formed at 350 degrees Celsius.

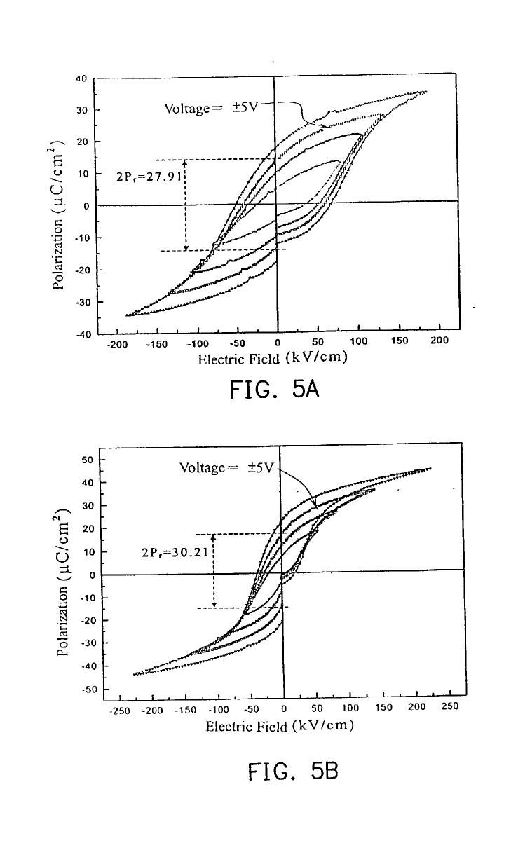

FIG. 4 is an X-ray diffraction pattern of a PZT thin film formed at 325 degrees Celsius to 450 degrees Celsius, wherein the PZT thin film is formed by sputtering under 5 mTorr of argon gas, with a power of 50 W, and the sputtering target is composed of Pb_{1.1}Zr_{0.53}Ti_{0.47}O₃. As shown in FIG. 4, as the temperature increases, the diffraction peak of PZT becomes more obvious, suggesting the extent of the Perovskite phase in the PZT thin film increases as the temperature increases.

Moreover, as shown in FIG. 4, at 350 degrees Celsius, the (100) and (200) direction of the PZT film is obvious, suggesting when the PZT thin film is crystallized at a temperature as low as 350 degrees Celsius. Additionally, after analyzing the X-ray diffraction pattern of the PZT thin film, the “a” axis for the PZT thin film lattice parameters is about 4.036 angstroms and the “c” axis is about 4.146 angstroms. The “a” axis for the LNO thin film is about 4.05 angstroms and the “c” axis is about 4.09 angstroms. Since the lattice parameters for the PZT thin film and for the LNO thin film are similar, the present invention can use an in-situ method to deposit a PZT thin film at a lower temperature, wherein the desired lattice structure is concurrently formed.

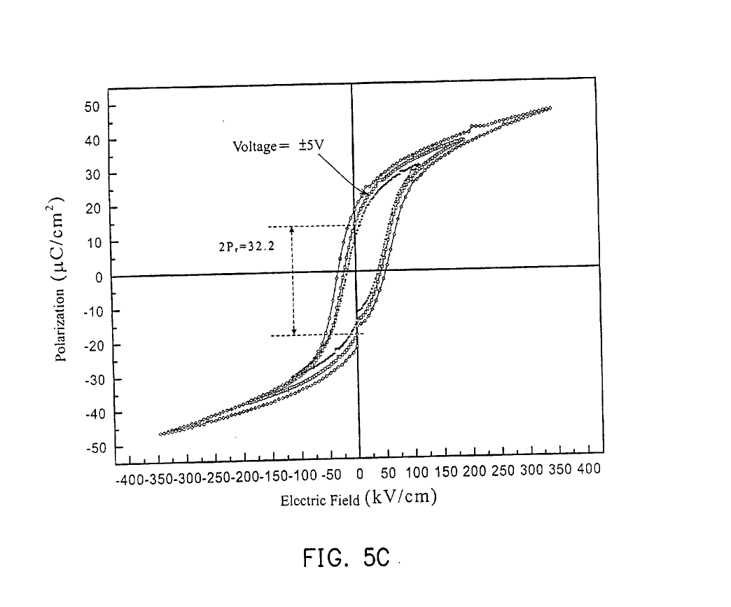

FIGS. 5A, 5B and 5C are ferroelectric hysteresis loops of the PZT thin film formed at temperatures of 375 degrees Celsius, 400 degrees Celsius and 450 degrees Celsius, respectively according to a preferred embodiment of the present invention.

The difference between the positive residual polarization and the negative residual polarization at zero electric field is depicted as 2Pᵣ. The testing results for the voltage difference between the upper and bottom electrodes that are within 5V and 5V are indicated by the arrows. As shown in FIGS. 5A, 5B and 5C, as the temperature increases, the 2Pᵣ. value increases when the voltage varies within 5V and 5V. The 2Pᵣ value is important for a FeRAM because for the writing of the binary data “1” in a regular device, the ferroelectric thin film in the capacitor of a FeRAM is caused to have a negative residual polarization value. For the writing of the binary data “0”, the ferroelectric thin film is caused to have a positive residual polarization value. As the difference between the positive polarization value and the negative polarization value increases, the difference between the readout signals for “0” and “1” becomes greater.

The probability of misinterpreting “0” and “1” thereby diminishes.

The above PZT thin film is formed by sputtering under a 5mTorr of Argon gas. The argon gas pressure, however, can be between 1 mTorr and 50 mTorr, adjusted according to the area of the target.

Moreover, the PZT thin film, which is formed on the LNO layer, by an in-situ method of epitaxally growing of the PZT thin film with the desired structure, which is the Perovskite phase. During the actual manufacturing process, the growing of the PZT thin film with the desired lattice structure on the LNO layer is accomplished at a temperature of about 350 degrees Celsius. In order to accommodate the low temperature requirement, the desired lattice structure for the LNO layer is also formed by an in-situ method of epitaxially growing the LNO layer at a temperature between 350 degrees Celsius to 500 degrees Celsius.

According to the present invention, the formation of the PZT thin film is achieved at a temperature lower to 350 degrees Celsius, which is far lower than that in the conventional practice. Additionally, the LNO layer that is formed under the PZT thin film is also formed at a temperature of about 350 degrees Celsius to 500 degrees Celsius and the lattice structure of the LNO layer is same as the desired lattice structure for the PZT thin film, which is the Perovskite phase. As a result, according to the present invention, the manufacturing of the metal interconnects can precede before the manufacturing of the capacitor to prevent problems of oxidation of interconnects, contamination of the machinery by the PZT thin film and damages inflicted upon the PZT thin film by plasma or hydrogen. Moreover, the PZT thin film is formed at a lower temperature, the PZT thin film of the present invention is therefore applicable in the fabrication of a ferroelectric memory device, a piezoelectric device or a pyroelectric device, wherein a damage to the substrate due to high temperature is prevented.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. An epitaxal growing method for a lead zirconate titanate (PZT) thin film with a lattice structure, comprising:providing a substrate;forming a lanthanum nickel oxide (LNO) thin film by an in-situ method such that the lanthanum nickel oxide (LNO) thin film is grown with a lattice structure; and forming the PZT thin film on the LNO thin film by an in-situ method such that the PZT thin film is epitaxially grown with a lattice structure the same as the LNO thin film at a temperature of about 350 to about 500 degrees Celsius.

2. The method of claim 1, wherein the PZT thin film grows at the temperature of about 350 to about 450 degrees Celsius.

3. The method of claim 1, wherein the LNO thin film grows at a temperature of about 350 to about 500 degrees Celsius.

4. The method of claim 1, wherein the epitaxal growing of the PZT thin film by sputtering uses a Pb_{y}ZrₓTi₁₋ₓO₃ (x and y are real numbers, y>1) target.

5. The method of claim 1, wherein the PZT thin film is formed under an argon gas environment.

6. The method of claim 1, wherein the PZT thin film is formed under an argon gas pressure of about 1 mTorr to about 50 mTorr.

7. The method of claim 1, wherein the method is applicable for a fabrication of a dynamic random access memory.

8. The method of claim 1, wherein the method is applicable for a fabrication of a ferroelectric random access memory.

9. The method of claim 1, wherein the method is applicable for a fabrication of a piezoelectric device.

10. The method of claim 1, wherein the method is applicable for a fabrication of a pyroelectric device.

11. The method of claim 1, wherein the lattice structure includes a Perovskite phase.

12. A fabrication method of a capacitor, comprising:providing a substrate;forming a barrier layer on the substrate;forming a lanthanum nickel oxide (LNO) thin film as a bottom electrode for the capacitor by an in-situ method such that the lanthanum nickel oxide (LNO) thin film is epitaxially grown with a lattice structure; and forming a lead zirconate titanat (PZT) thin film on the LNO thin film by the in-situ method such that the PZT thin film with a lattice structure the same as the LNO thin film is epitaxially grown at a temperature of about 350 to about 500 degrees Celsius.

13. The method of lcaim 12, wherein the substrate comprises CMOS (complementary metal oxide semiconductor) devices and interconnects.

14. The method of claim 12, wherein a metal interconnect structure and an inter-metal dielectric layer are already formed on the substrate, and the barrier layer is formed on top of the inter-metal dielectric layer.

15. The method of claim 12, wherein the barrier layer is selected from the group consisting of titanium, titanium nitride, titanium oxide, titanium tungsten nitride, titanium aluminum nitride, tantalum nitride and platinum.

16. The method of claim 12, wherein an upper electrode is selected from the group consisting of lanthanum nickel oxide, platinum, iridium dioxide, ruthenium dioxide, ruthenium and iridium.

17. The method of claim 12, wherein the PZT thin film grows at a temperature of about 350 degrees Celsius to 450 degrees Celsius.

18. The method of claim 12, wherein the LNO thin film grows at a temperature of about 350 degrees Celsius to 500 degrees Celsius.

19. The method of claim 12, wherein sputtering the substrate uses a Pb_{y}ZrₓTi₁₋ₓO₃ (x and y are integers, y>1) target.

20. The method of claim 12, wherein the PZT thin film grows under an argon environment.

21. The method of claim 12, wherein the lattice structure includes a Perovskite phase.
